(19) United States
(12) Patent Application Publication
(10) Pub. No.: US 2002/0005759 A1
(43) Pub. Date: Jan. 17, 2002

(54) Ultra complementary audio amplifier output stage

(76) Inventor: Teck Lee Wong, Kuala Lumpur (MY)

Correspondence Address: DR. WONG, TECK LEE, 24, JALAN SETIAMURNI 4, BUKIT DAMANSARA, KUALA LUMPUR, MY

(21) Appl. No.: 09/877,789

(22) Filed: Jun. 11, 2001

(30) Foreign Application Priority Data
Jul. 12, 2000 (MY) PI 20003198

(51) Int. Cl. H03F 3/26

(52) U.S. Cl. 330/267

(57) ABSTRACT

The Ultra Complementary Output Stage utilises both direct and bootstrapped drive for the output power devices in audio frequency power amplifiers operating in Class A, Class AB or Class B, in emitter follower, Sziklai pair/hybrid, or compound (eg. triple) configurations.

### CROSS REFERENCE TO RELATED APPLICATIONS

Not Applicable.

### STATEMENT REGARDING FEDERALLY SPONSORED RESEARCH OR DEVELOPMENT

Not Applicable.

### REFERENCE TO A MICROFICHE APPENDIX

Not Applicable.

### BACKGROUND OF THE INVENTION

This invention relates to circuits for audio frequency power amplifier's push-pull output stage. (Class: 330, Amplifiers.)

The complementary devices (P & N MOSFETs, or PNP & NPN Bipolar transistors) used in an audio amplifier push-pull output stage are assumed to be fully complementary.

Deviation from fully complementary characteristics may arise from device design and production tolerances. The result is an increased total harmonic distortion (THD).

In particular, in Class A push-pull output stages, the deviation from fully complementary characteristics results in increased THD with respect to increasing frequency and degradation of power supply rejection ratio with respect to increasing frequency.

### BRIEF SUMMARY OF THE INVENTION

Driving both halves of the push-pull output stage with an identical signal will improve even order harmonics cancellation in Class A operation.

The identical drive signal can be achieved by summing the drive signals from both halves.

Using two independent drivers, one for each half, driver interaction is minimised.

### BRIEF DESCRIPTION OF THE SEVERAL VIEWS OF THE DRAWING

FIG. 1 shows a low power Class A push-pull Sziklai pair output stage with two Output Power Devices (OPD), featuring the Mutual Bootstrap Capacitor (MBC) which ties the OPDs together at operating frequencies. The OPDs may be bipolar transistors or MOSFETs.

FIG. 2 shows a low power Class A push-pull EF output stage with two OPDs. The Mutual Bootstrap Capacitor acts as in FIG. 1.

FIG. 3 shows a development of FIG. 1, a class A push-pull Sziklai pair output stage for four OPDs. The MBCs, as before, bootstrap all the OPDs together at operating frequencies. The OPDs may be bipolar transistors or MOSFETs.

FIG. 4 Shows the implementation of Ultra Complementary Class B push-pull ‘Sziklai’ MOSFET hybrid pair output stage. Such a configuration will enable both the quiescent current and the transient current to be more accurately shared between the MOSFETs as they are now determined by the V_{be} of the bipolar transistors instead of manufacturing tolerances of MOSFETs. The MBCs ensure that the MOSFETs see the summed gate drive signal from the driving devices operating in the same duty cycle.

FIG. 5 shows the Ultra Complementary Audio Amplifier Output Stage implemented in a compound (triple based) push pull output stage with two MBCs bootstrapping the OPDs which are operating in the same phase.

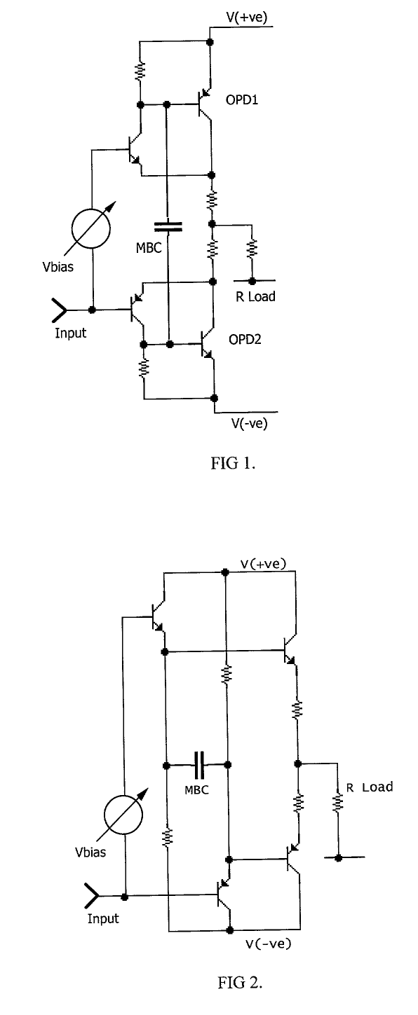

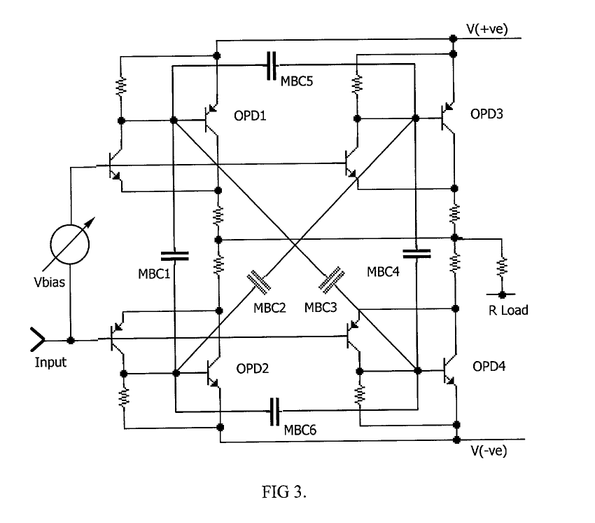

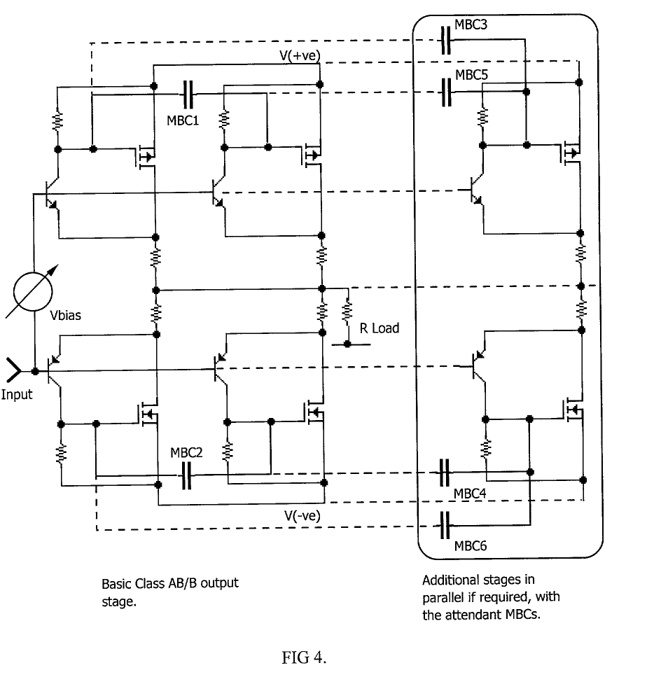

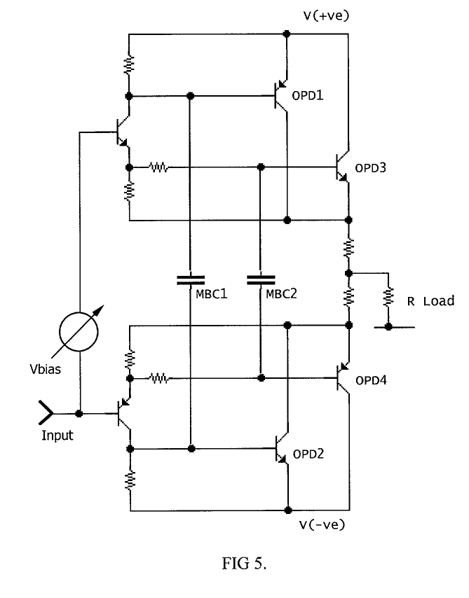

### DETAILED DESCRIPTION OF THE INVENTION

The present invention aims to improve the complementary characteristics of the push-pull audio amplifier output stage from the output drivers.

The present invention is applicable to the Sziklai pair output stage, the ‘Sziklai’ MOSFET hybrid output stage, the emitter follower (EF) output stage and compound (eg. triple) output stages by forcing the output power devices (OPD) to be driven by a combined signal derived from it's driving device and from at least one other driving device.

By using more than one independent driver connected together by bootstrapping, the transfer function of the drivers are summed. As the drivers are independent, the interaction between them remained minimal.

Operating in class A, the summed driving signal improves the cancellation of the even order harmonics. As both halves see an identical signal, such cancellation is therefore limited only by the deviation from the complementary characteristics of the two final devices. (This can be further minimised by local negative feedback. e.g. Sziklai configration.)

The power supply rejection ratio of such a stage will also be enhanced by the improved cancellation resulting from the above enhanced complementarity.

Class B output stages will benefit from the averaging of the devices' individual characteristics due to deviation within the manufacturer's tolerance.

I claim:

1. The Ultra Complementary Audio Amplifier Output Stage working in Class A, Class AB or Class B is characterized by the output power devices being connected a) directly to one or more driving devices, and, b) by bootstrap (eg. by using the Mutual Bootstrap Capacitor) to one or more driving devices.

2. The device that provides the bootstrap drive is characterized by working independantly of the device that provides the direct drive.
